(19) United States
(12) Patent Application Publication
(10) Pub. No.: US 2006/0091444 A1
(43) Pub. Date: May 4, 2006

(54) Double word line memory structure and manufacturing method thereof

(75) Inventor: Fuja Shone, Hsinchu (TW)

Correspondence Address: OLIFF & BERRIDGE, PLC, P.O. BOX 19928, ALEXANDRIA, VA, 22320, US

(73) Assignee: SKYMEDI CORPORATION, Hsinchu (TW)

(21) Appl. No.: 10/980,164

(22) Filed: Nov. 4, 2004

(51) Int. Cl. H01L 21/336; H01L 29/76

(52) U.S. Cl. 257/314; 438/258

(57) ABSTRACT

A memory structure comprises two bit lines, a first gate dielectric, a second gate dielectric, at least one first gate, a second gate and a third gate, a first dielectric spacer and a second dielectric spacer, where the two bit lines are formed in the semiconductor substrate, the first gate dielectric, and the second gate dielectric are between the two bit lines, in which at least one of the first and second gate dielectrics includes a silicon nitride. For instance, a first gate dielectric is made of ONO, whereas the second gate dielectric is composed of silicon oxide. The first gate is formed above the first gate dielectric, the second gate is formed above the second gate dielectric and is substantially perpendicular to the first gate, and the third gate is substantially parallel to the second gate. The second gate is insulated from the first gate by the first dielectric spacer, whereas the second gate is insulated from the third gate by the second dielectric spacer. As a result, one more gate serving as a word line in a certain area is added, and thus the word line density can be almost doubled.

### BACKGROUND OF THE INVENTION

(A) Field of the Invention

The present invention is related to a memory structure and manufacturing method thereof, and more specifically to a memory structure including non-volatile cells and manufacturing method thereof.

(B) Description of the Related Art

Among semiconductor memories, nonvolatile memories, especially the electrically erasable programmable read only memory (EEPROM) is particularly useful due to its advantage of retaining information even power is turned off, and its application also becomes more popular. Higher density and higher speed are two critical targets in the development of nonvolatile memories. One approach to increase the memory density is the introduction of multi-level programming systems for the memory cells thereof, which conventionally store one bit per each memory cell. However, more complicated process and peripheral circuitry are needed for the manufacture and operations of a memory when multilevel programmability of the memory cells is used. Basically, each memory cell structure can be applied with multilevel programming system only that proper peripheral circuitry is employed accompanying with the memory array, and simplified operation circuit and method are desired. Another approach for high-density nonvolatile memories is to store two bits in a single memory cell, and there are several prior arts have been proposed, for example U.S. Pat. Nos. 5,768,192, 5,963,465 and 6,011,725 issued to Eitan. Similar to other semiconductor memories, the nonvolatile memory is also developed toward scale down to increase the memory capacity, and new and improved memory cell structures and better programming mechanisms are proposed to improve the performance thereof. To increase the density of memory circuit and simplify its manufacture process, oxide-nitride-oxide (ONO) structure has been used to replace the conventional stack memory cell. Further increment of memory density is provided, for example, by U.S. Pat. No. 5,424,569 issued to Prall and U.S. Pat. No. 6,248,633 issued to Ogura et al.

A two-bit nonvolatile memory cell disclosed in U.S. Pat. No. 6,011,725 is provided herewith in FIG. 1 to illustrate its structure and operations. On a semiconductor substrate 10, two bit lines 12 and 14 are formed with a gate above therebetween. The gate includes a gate dielectric such as a silicon nitride 18 sandwiched between two oxides 16 and 20 and a gate 22 on the gate dielectric. The silicon nitride 18 is programmable with two bits 24 and 26 on its two sides next to the bit lines 12 and 14, respectively. Even though this art increases the memory capacity, the scaling becomes an issue since these two bits under the same gate will influence each other. Moreover, multi-level programming is difficult to implement in this memory cell.

Another memory cell is proposed by Sasago et al. in “10-MB/s Multilevel Programming of Gb-Scale Flash Memory Enabled by New AG-AND Cell Technology”, IEEE IEDM, p. 952-955 (2002). The cell structure of this art is provided in FIG. 2, in which a semiconductor substrate 28 is implanted with punch through regions 30 and bit lines 32, a gate oxide 34 and its corresponding assist gate 36 are formed above a channel between the punch through region 30 and bit line 32, a tunnel oxide 38 and a floating gate 40 are formed above the other side of the punch through region 30 between another bit line 32, an ONO dielectric 42 is formed on the floating gate 40, and a polysilicon 44 is further formed thereon. This art achieves a high speed multi-level programming, while brings complex process technology and circuit of the memory cell and its control circuit.

The U.S. patent application Ser. No. 10/698,514, invented by the same inventor of this application, disclosed a common spacer dual gate memory cell as shown in FIG. 3. A non-volatile memory array is formed on a silicon substrate 50, of which a gate oxide 96, a first poly-gate 62 and a cap 64 composed of silicon nitride are sequentially formed thereon. Sequentially, two dielectric spacers 66 are formed beside the first poly-gate 62 each, and then dopants are tilted implanted into the substrate 50 to form N⁺ regions 52. Then, an ONO dielectric 72 and a polysilicon layer or a polycide layer are formed and patterned to form gates 68.

The gates 68 may serve as word lines and oxide insulators will be disposed therebetween, which is substantially referred as a standard structure. The oxide insulators somewhat occupy space to hinder the improvement of word line integrity.

In view of the above, there is still a need of modified or new cell structure advantageous to nonvolatile memories, with a view to simplifying the operation and circuit, as well as increasing the integrity density of the memory.

### SUMMARY OF THE INVENTION

The objective of the present invention is to provide a memory structure with higher integrity, e.g., word line density, and manufacturing method thereof.

To achieve the above objective, a memory structure on a semiconductor substrate, e.g., a silicon substrate, is disclosed. The memory structure comprises two bit lines, a first gate dielectric, a second gate dielectric, a first gate, a second gate and a third gate, a first dielectric spacer and a second dielectric spacer, where the two bit lines are formed in the semiconductor substrate, the first gate dielectric and the second gate dielectric are formed on the substrate and transversely formed between the two bit lines, in which at least one of the first and second gate dielectrics includes a silicon nitride layer. For instance, the first gate dielectric is made of ONO, whereas the second gate dielectric is composed of silicon oxide. The first gate is formed on the first gate dielectric, the second gate is formed on the second gate dielectric and is substantially perpendicular to the first gate, and the third gate is substantially parallel to the second gate.

The second and third gates are insulated from the first gate by the first dielectric spacer, whereas the second gate is insulated from the third gate by the second dielectric spacer. The above memory structure can be manufactured by the following process. First, a first gate dielectric is formed on a semiconductor, and then a plurality of first gates are formed on the first gate dielectric. Next, dopants are implanted to form a plurality of bit lines besides the first gates.

Then, a plurality of first dielectric spacers on sidewalls of the first gates, and a plurality of second gates substantially perpendicular to the first gates with a second gate dielectric are formed on the semiconductor substrate uncovered by the first gates. A plurality of second dielectric spacers are formed on sidewalls of the second gates, and then a plurality of third gates substantially parallel to the second gates are formed. In view of the above, in addition to the second gate serving as a word line, the third gate serving as another word line is further added within a certain area in comparison with a traditional memory structure. Therefore, the integrity of memory cells can be increased tremendously.

### BRIEF-DESCRIPTION OF THE DRAWINGS

FIG. 1 illustrates a known two-bit nonvolatile memory cell;

FIG. 2 illustrates a known AG-AND-type memory cell;

FIG. 3 illustrates a nonvolatile memory structure illustrated in U.S. patent application Ser. No. 10/698,514 invented by the same inventor of the present invention;

FIGS. 4 through 20 and FIGS. 22 and 23 illustrate the method for manufacturing a memory structure in accordance with the present invention;

FIGS. 20(a) and 21 illustrate a memory structure comprising multiple gates disposed in series between two bit lines of the present invention; and

FIG. 24 illustrates a memory structure comprising floating gates of the present invention.

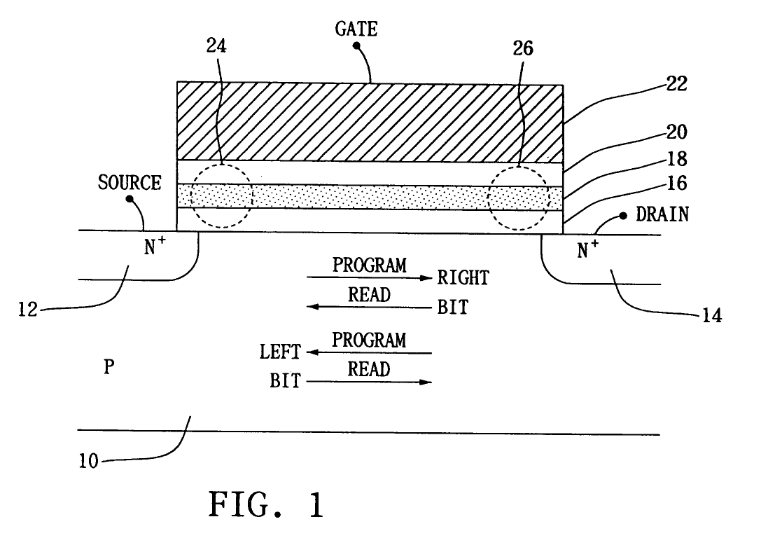

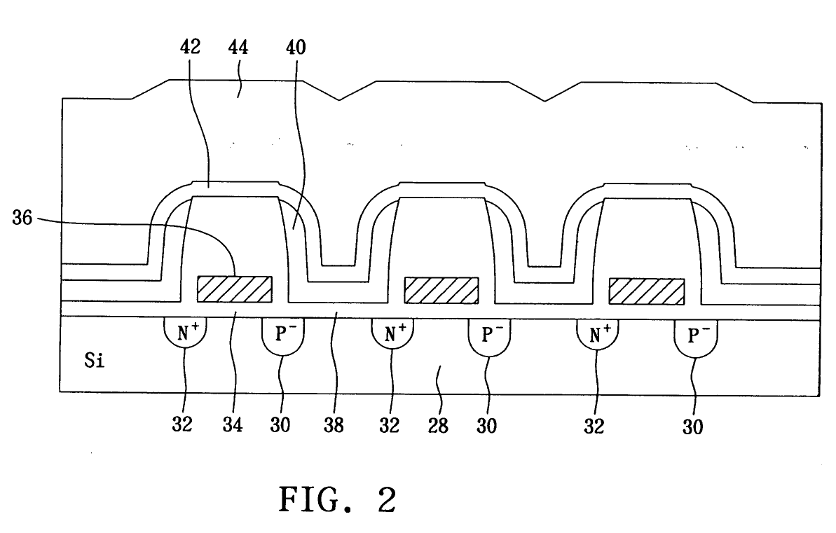

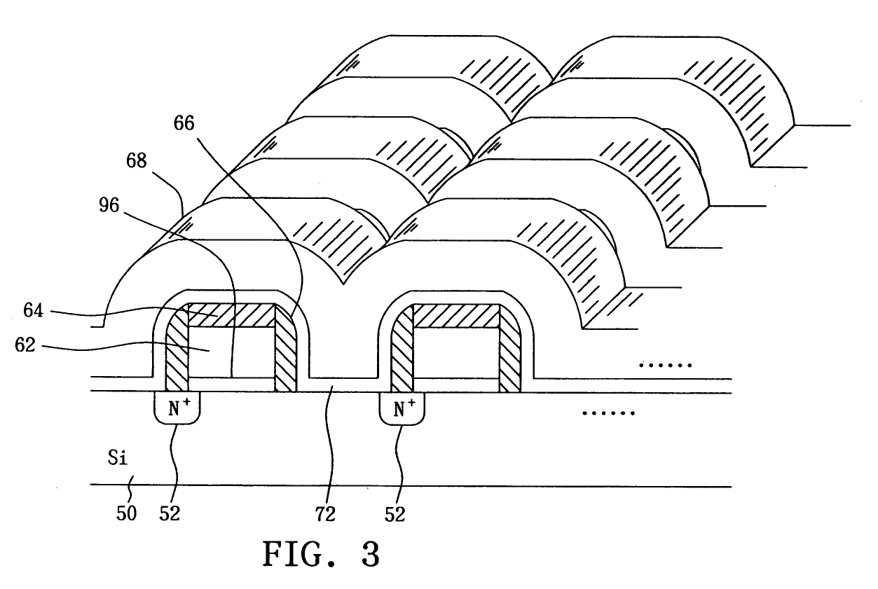

### DETAILED DESCRIPTION OF THE INVENTION

Embodiments of the present invention are now being described with reference to the accompanying drawings.

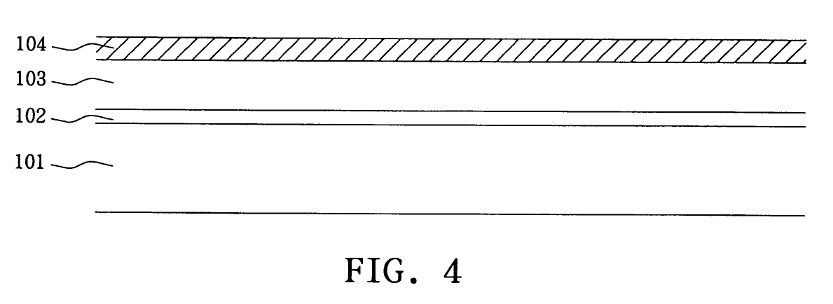

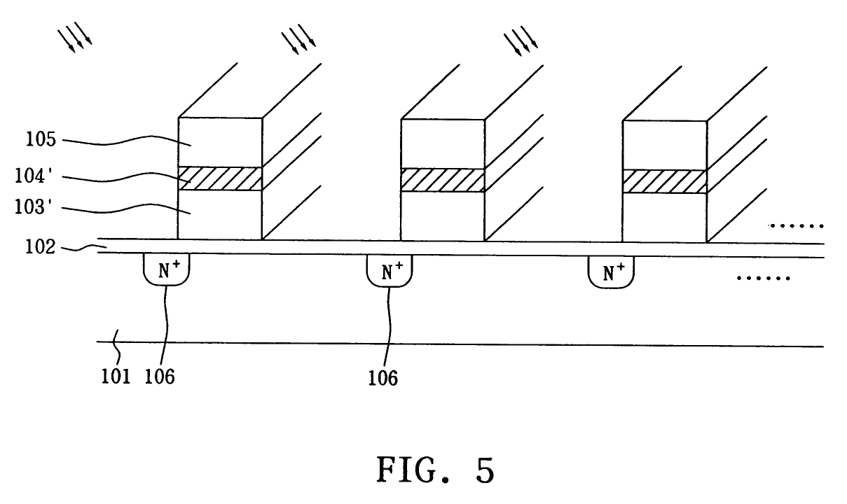

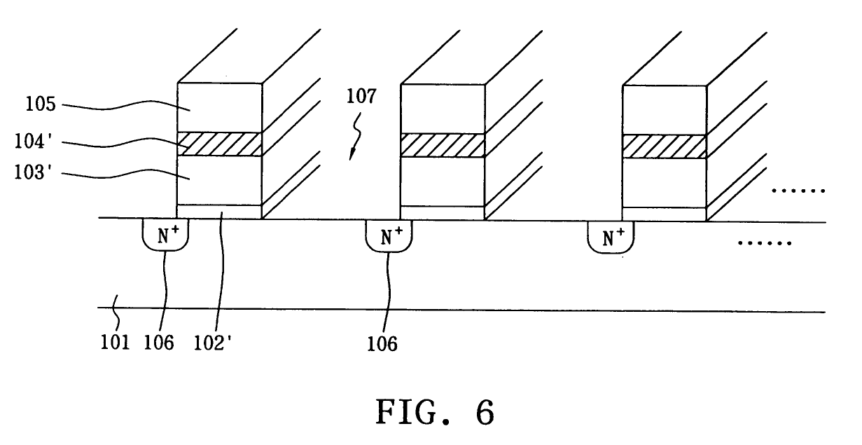

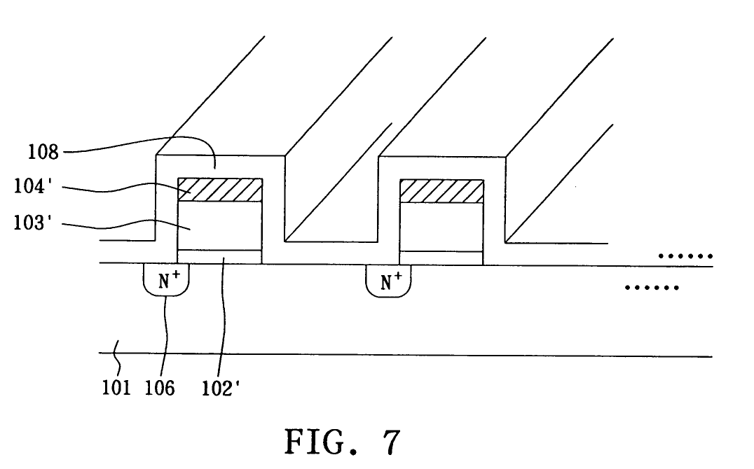

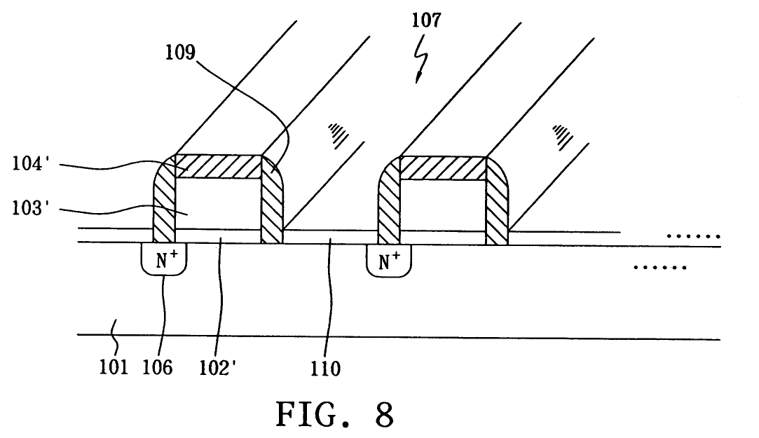

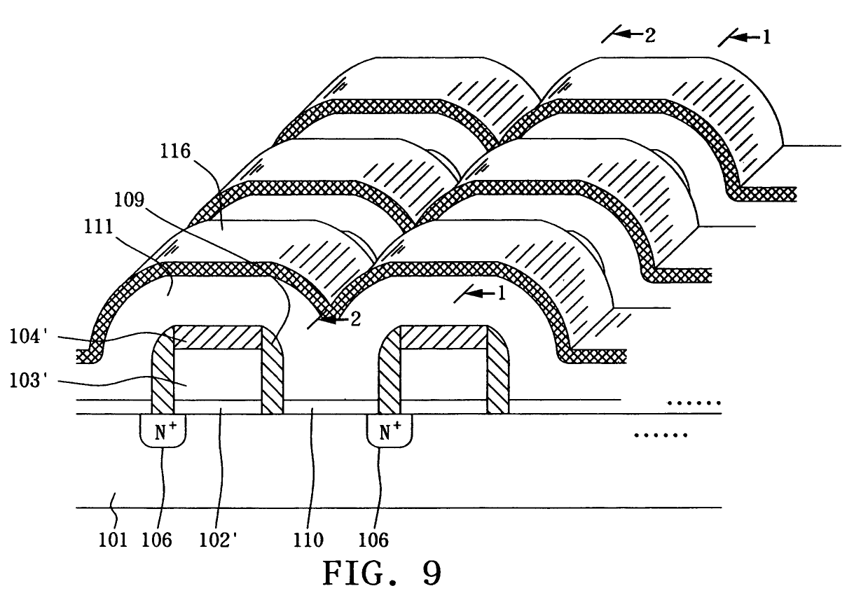

An embodiment process for forming a memory array is shown in FIGS. 4 through 20. Referring to FIG. 4, an ONO layer 102 and a gate conductor 103 composed of, for example, polysilicon are deposited on a substrate 101, and a silicon nitride layer 104, or oxide layer, is further deposited on the gate conductor 103. Then, the nitride layer 104 and gate conductor 103 are patterned with a photoresist 105, followed by being etched to form first gates 103′ and their caps 104′ as shown in FIG. 5. Sequentially, dopants such as arsenic ions on the order of 5×10¹⁴ to 5×10¹⁵ atoms/cm² are tilted-implanted to form bit lines 106 each on one side of the first gates 103′, and the ONO layer 102 is etched to leave a portion thereof as nitride gates 102′ underlying the first gates 103′. Consequently, the substrate 101 at spaces 107 between the first gates 103′ is exposed as shown in FIG. 6. In FIG. 7, the photoresist 105 is stripped off and then a CVD (chemical vapor deposition) oxide 108 is deposited. As shown in FIG. 8, dielectric spacers 109 are formed on sidewalls of the first gates 103′ by etching the CVD oxide 108, and a dielectric layer 110, e.g., an oxide layer, is further formed on the substrate 101. As shown in FIG. 9, a polysilicon or tungsten silicide layer are deposited and patterned to form second gates 111 serving as word lines, and each second gate 111 is capped with a silicon nitride layer 116 as a mask for sequential process. The second gates 111 are insulated from the first gates 103′ by the dielectric spacers 109 and are substantially perpendicular to the first gates 103′ in light of their longitudinal extending directions.

Because charges can be locally trapped in an ONO layer, the ONO layer 102′ serving as nitride gates can be continuous.

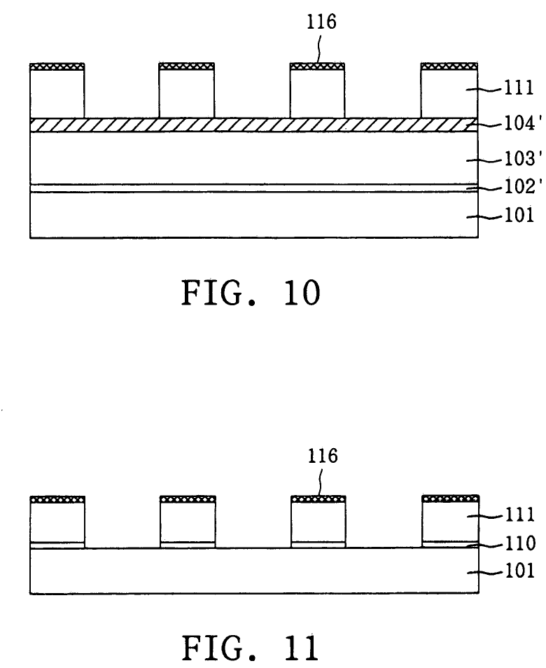

FIGS. 10 and 11 illustrate the cross-sectional views of the line 1-1 and line 2-2 in FIG. 9, respectively. In FIG. 10, the second gates 111 and the nitride caps 116 are positioned above the stack of the substrate 101, the ONO layer 102′, the first gate 103′ and the cap 104′. In FIG. 11, the second gates 111, the dielectric layer 110 and the nitride caps 116 are positioned above the substrate 101. The portion of the dielectric layer 110 uncovered by the second gates 111 is stripped away in the etching process.

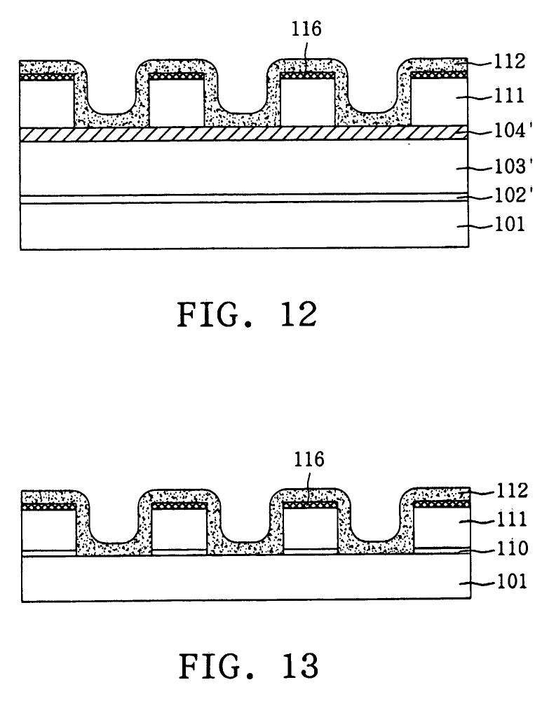

The following process viewed from the line 1-1 is illustrated in FIGS. 12, 14, 16 and 18, whereas those viewed from the line 2-2 is illustrated in FIGS. 13, 15, 17 and 19, respectively corresponding to FIGS. 12, 14, 16 and 18 at each step.

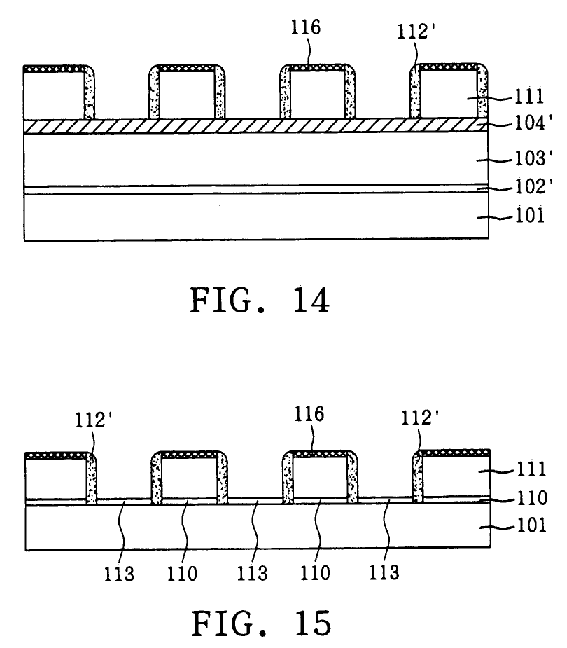

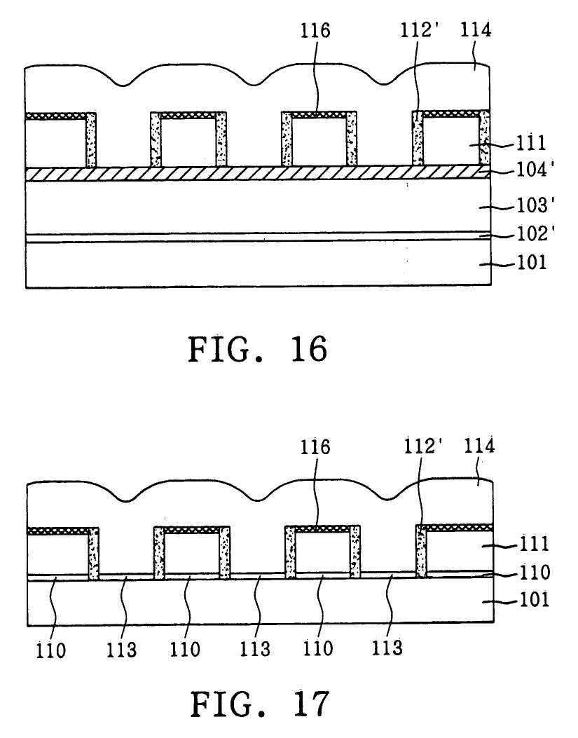

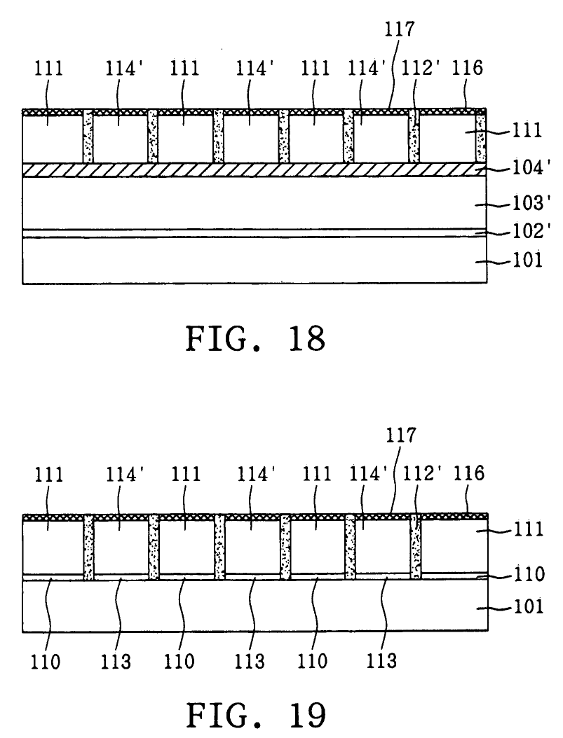

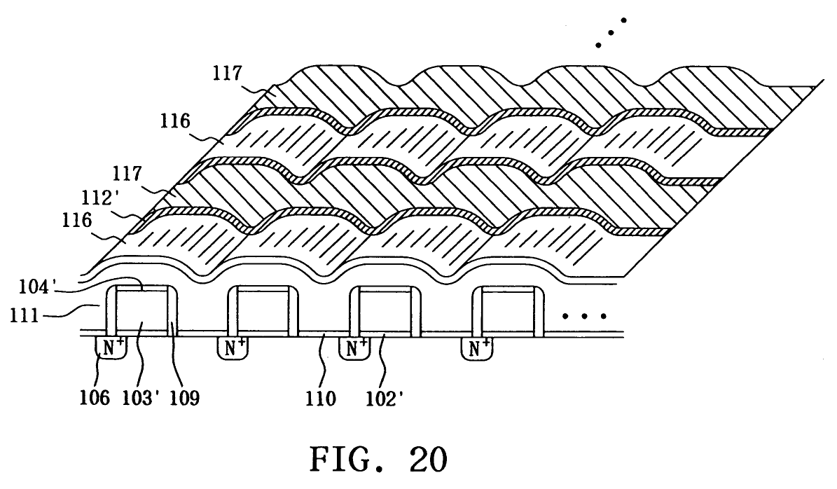

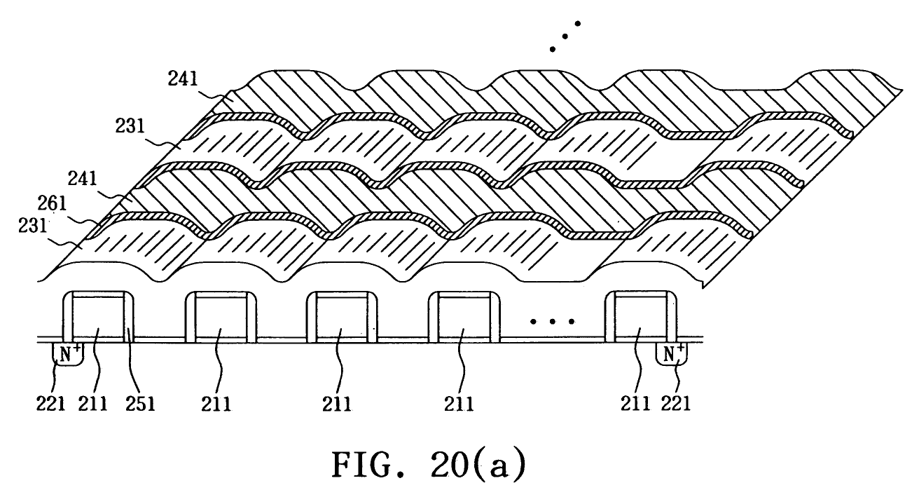

In FIG. 12, a dielectric layer 112 is deposited on the first gates 111 and the nitride layer 104′, whereas in FIG. 13 the dielectric layer 112 is deposited on the first gates 111 and the silicon substrate 101. In FIGS. 14 and 15, dielectric spacers 112′ are formed by etching the dielectric layer 112. In FIG. 15, in addition to the formation of the dielectric spacers 112′, gate oxides 113 are further formed on the exposed substrate 101 by either thermal growth or deposition. Alternatively, the dielectric spacers 112′ may be formed with the gate oxides 113 at the same time by thermal growth. As shown in FIGS. 16 and 17, a polysilicon layer 114 is deposited, and then is planarized to form third gates 114′. Then, dielectric layers 117 are formed thereon by, for example, thermal oxidation, as shown in FIGS. 18 and 19. FIG. 20 is a schematic view of the memory structure at this stage. The third gates 114′ serving as word lines are also substantially parallel to the second gates 111 and insulated from the second gates 11 by the dielectric spacers 112′. Further, the third gates 114′ are insulated from the first gates 103′ by spacers 109 also. Accordingly, the dielectric spacers 109 and 112′ are substantially perpendicular to each other. As a result, one more gate serving as a word line in a certain area is added, thus, ideally, the word line density can be almost doubled.

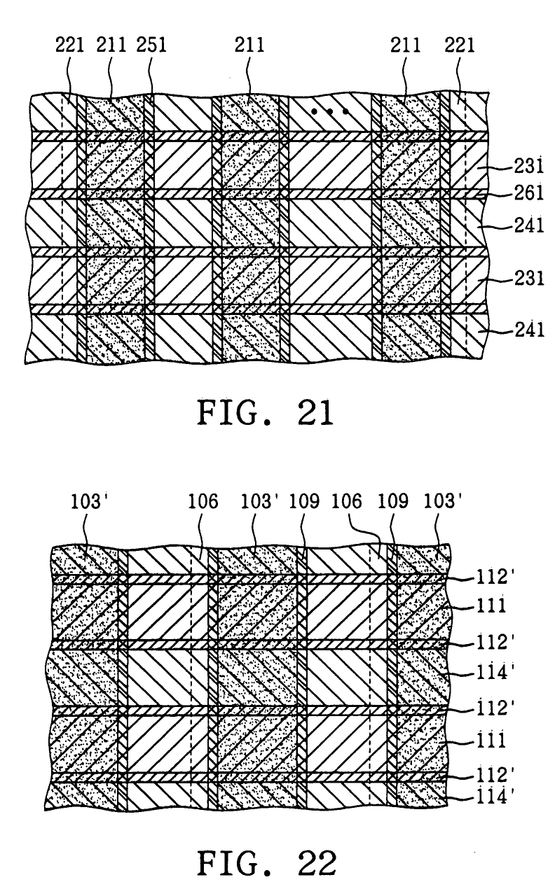

To those who skilled in the art, it is obvious that the embodiment shown in FIGS. 4 through 20, the locations of the ONO layer 102′ and gate dielectric 110 can be interchanged, and the memory structure in accordance with the present invention still remains the same functions. Further, a similar process can be also implemented to form an NAND-like structure, i.e., a plurality of first gates are formed in series between two bit lines, as shown in FIG. 20(a), in which the implantation process is performed after first gates 211 are formed and masked by photoresist, so as to form two bit lines 221 at two sides of the group of the first gates 211. Then, the second gates 231 perpendicular to the first gates 211 are formed. Starting from here, the sequential processes are performed in light of those shown in FIGS. 10 to 19, so as to form third gates 241 parallel to the second gates 231. The second gates 231 and the third gates 241 are insulated from the first gates 251 by dielectric spacers 251, and the second gates 231 are insulated from the third gates 241 by dielectric spacers 261. FIG. 21 illustrates the top view of the memory structure shown in FIG. 20(a).

FIG. 22 illustrates the top view of the memory structure shown in FIG. 20, in which first gates 103′ are perpendicular to the second and third gates 111 and 114′ and insulated from the second and third gates 111 and 114′ by the spacers 109, and the second gates 111 are insulated from the third gates 114′ by spacers 112′. Normally, the width of the dielectric spacer 109 or 112′ are in the range of 100 to 500 angstroms, whereas the width of the gate 111 and 114′ is in the range of 300 to 3000 angstroms, depending upon the design rule.

By the illustration of the above embodiments and descriptions, the inventive nonvolatile memory array has an increased memory density by introducing perpendicular spacers to insulate the gates 103′, 111 and 114′.

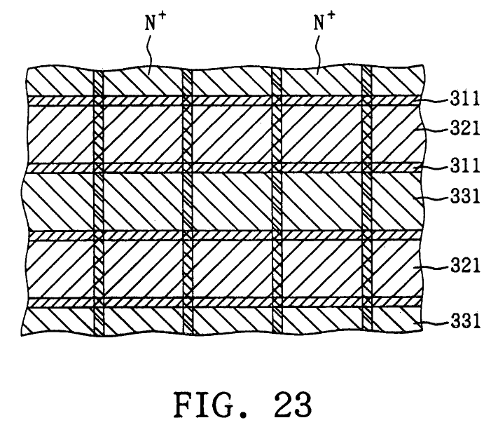

Moreover, the above process can also be implemented into a basic memory structure as shown in FIG. 23, in which the gates 321 and 331 are insulated from each other by spacers 311 and perpendicular to the N+ bit lines. Likewise, the word line density can be increased.

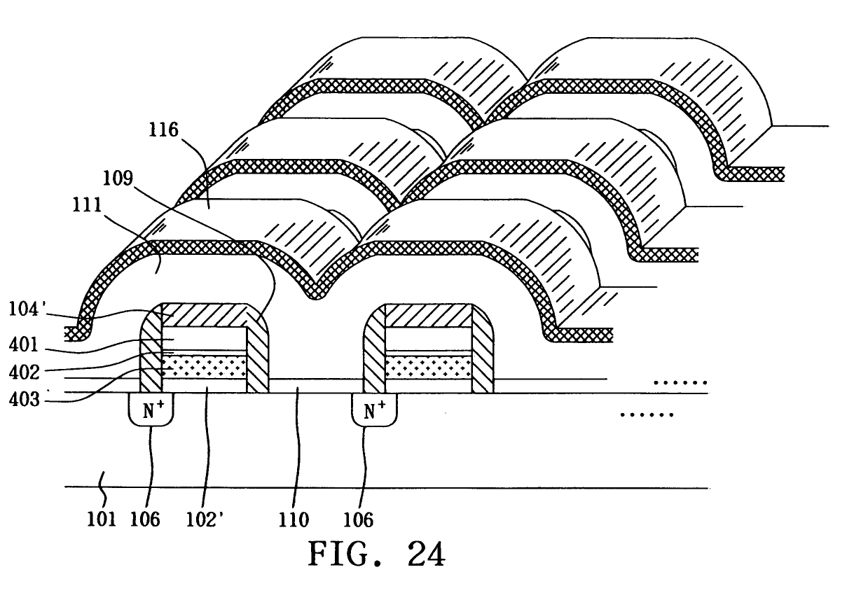

Referring to FIG. 9 again, in the case of implementation for a floating gate structure, each first gate 103′ is replaced with floating gates 403, an ONO layer 402 and a control gate 401 as shown in FIG. 24. The floating gates 403 are aligned and below the control gate 401. Each floating gate 403 is in the form of a block for each memory cell, whereas the control gate 401 is continuous and used for controlling the plurality of floating gates 403 thereunder. The dielectric layer 110 may comprise a nitride film as a storage layer.

In addition to the application to a non-volatile memory cell of NMOS type as the above mentioned, a memory cell of PMOS type can also be implemented without departing from the spirit of the present invention.

The above-described embodiments of the present invention are intended to be illustrative only. Numerous alternative embodiments may be devised by those skilled in the art without departing from the scope of the following claims.

What is claimed is:

1. A memory structure on a semiconductor substrate, comprising:
two bit lines formed in the semiconductor substrate;
a first gate dielectric and a second gate dielectric formed on the semiconductor substrate between the two bit lines;
at least one first gate formed on the first gate dielectric;
a second gate formed above the second gate dielectric and being substantially perpendicular to the first gate;
a third gate formed substantially parallel to the second gate;
a first dielectric spacer between the first and second gates; and
a second dielectric spacer between the second and third gates;
wherein at least one of the first and second gate dielectrics includes a silicon nitride layer.

2. The memory structure in accordance with claim 1, wherein the second gate has a portion crossing over and isolated from the first gate.

3. The memory structure in accordance with claim 1, wherein the second gate has a portion crossing over the first dielectric spacer.

4. The memory structure in accordance with claim 1, wherein the first dielectric gate is an oxide/nitride/oxide layer.

5. The memory structure in accordance with claim 1, wherein a plurality of first gates are formed in series between the two bit lines.

6. The memory structure in accordance with claim 1, further comprising a plurality of floating gates below the first gate, wherein the first gate serves as a control gate for the plurality of floating gates.

7. The memory structure in accordance with claim 5, further comprising a plurality of floating gates below each first gate, wherein each first gate serves as a control gate for the plurality of floating gates.

8. A memory structure on a semiconductor substrate, comprising:
two bit lines formed in the semiconductor substrate;
a first gate dielectric and a second gate dielectric formed on the semiconductor substrate and transversely disposed between the two bit lines;
a first gate formed on the first gate dielectric;
a second gate formed above the second gate dielectric and being substantially parallel to the first gate; and
a dielectric spacer between the first and second gates;
wherein at least one of the first and second gate dielectrics includes a silicon nitride layer.

9. The memory structure in accordance with claim 8, further comprising a plurality of floating gates below the first gate, wherein the first gate serves as a control gate for the plurality of floating gates.

10. A method for forming a memory structure, comprising the steps of:
forming a plurality of first gates above a semiconductor substrate;
implanting dopants to form a plurality of bit lines next to the first gates;
forming a plurality of first dielectric spacers on sidewalls of the first gates;
forming a plurality of second gates above the semiconductor substrate and being substantially perpendicular to the first gates;
forming a plurality of second dielectric spacers on sidewalls of the second gates; and
forming a plurality of third gates above the semiconductor substrate and being substantially parallel to the second gates.

11. The method for forming a memory structure in accordance with claim 10, further comprising the step of forming a first gate dielectric on the semiconductor substrate before forming the first gates.

12. The method for forming a memory structure in accordance with claim 11, wherein the first gate dielectric comprises a silicon nitride layer.

13. The method for forming a memory structure in accordance with claim 10, further comprising the step of forming a second gate dielectric before forming the second gates.

14. The method for forming a memory structure in accordance with claim 10, wherein the formation of the first dielectric spacers comprises the steps of depositing an dielectric layer and etching the dielectric layer for leaving portions thereof on the sidewalls of the first gates.

15. The method for forming a memory structure in accordance with claim 10, wherein the formation of the second dielectric spacers comprises the steps of depositing an dielectric layer and etching the dielectric layer for leaving portions thereof on the sidewalls of the second gates.

16. The method for forming a memory structure in accordance with claim 10, wherein at least one of the first and second dielectric spacers are formed by thermal growth.

17. The method for forming a memory structure in accordance with claim 10, wherein at least one of the first and second gate dielectrics are formed by thermal growth.

18. The method for forming a memory structure in accordance with claim 10, wherein the dopants are implanted with a tilted angle.

19. The method for forming a memory structure in accordance with claim 10, wherein the third gates are formed by deposition and planarization processes.

20. The method for forming a memory structure in accordance with claim 10, further comprising the step of forming dielectric layers on top of the third gates by thermal oxidation.
